(19) United States
(12) Patent Application Publication
(10) Pub. No.: US 2015/0116013 A1
(43) Pub. Date: Apr. 30, 2015

(54) INTEGRATED CIRCUIT

(71) Applicant: Samsung Electro-Mechanics Co., Ltd., Suwon-Si (KR)

(72) Inventors: Je Hyeon YU, Suwon-Si (KR); Yun Joong LEE, Suwon-Si (KR); Sang Hyun CHA, Suwon-Si (KR); Chang Seok LEE, Suwon-Si (KR); Hye Jin LEE, Suwon-Si (KR); Deuk Hee PARK, Suwon-Si (KR)

(73) Assignee: SAMSUNG ELECTRO-MECHANICS CO., LTD., Suwon-Si (KR)

(21) Appl. No.: 14/273,236

(22) Filed: May 8, 2014

(30) Foreign Application Priority Data
Oct. 31, 2013 (KR) 10-2013-0131615

(51) Int. Cl. H03K 17/16

(52) U.S. Cl. CPC H03K 17/162; H03K 2217/0027
USPC 327/143

(57) ABSTRACT

There is provided an integrated circuit controlling a power supply, the integrated circuit including: an HV pin obtaining startup power; a voltage dividing unit connected to the HV pin; and an input voltage detecting unit detecting an input voltage through voltage distribution by the voltage dividing unit. The integrated circuit may be capable of reducing manufacturing costs by omitting a separate voltage sensing pin.

### CROSS-REFERENCE TO RELATED APPLICATION

This application claims the benefit of Korean Patent Application No. 10-2013-0131615 filed on Oct. 31, 2013, with the Korean Intellectual Property Office, the disclosure of which is incorporated herein by reference.

### BACKGROUND

The present disclosure relates to an integrated circuit capable of controlling a power supply.

In general, electronic apparatuses use a power supply for a supply of driving power in order to implement operations thereof.

Such a power supply mainly uses a power factor correction apparatus and a direct current to direct current (DC/DC) converter.

The power factor correction apparatus serves to allow a power factor, a performance index related to a phase difference between a voltage and a current of input power and distortion of the current, to be close to 100%.

In the case in which the power factor is 100%, the voltage and the current have the same phase and the current is not distorted. Accordingly, a load is operated as a pure resistive load, such that only active power is used.

In this case, a power supply only needs to supply active power to actually be used, and does not need to supply reactive power which will not be used. Therefore, there is no waste in the supplying of power, resulting in an increase in efficiency.

Accordingly, a general power supply may achieve a high power factor by using a power factor correction apparatus.

A DC/DC converter may switch DC power input to an electronic apparatus to provide DC power having a voltage level appropriate for the driving thereof.

The power supply described above needs to sense an input voltage.

### RELATED ART DOCUMENT

(Patent Document 1) Japanese Patent Laid-Open Publication No. 2010-206988
(Patent Document 2) Japanese Patent Laid-Open Publication No. 2005-080395

### SUMMARY

An aspect of the present disclosure may provide an integrated circuit capable of sensing an input voltage using an HV pin and a drain pin.

An aspect of the present disclosure may also provide an integrated circuit capable of reducing manufacturing costs by omitting a separate voltage sensing pin.

According to an aspect of the present disclosure, an integrated circuit controlling a power supply may include: an HV pin obtaining startup power; a voltage dividing unit connected to the HV pin; and an input voltage detecting unit detecting an input voltage through voltage distribution by the voltage dividing unit.

The voltage dividing unit may include a plurality of resistors connected to each other in series.

The integrated circuit may further include a VDD pin transferring the startup power obtained by the HV pin to a capacitor.

The integrated circuit may further include: a startup switch interrupting a connection between the HV pin and the VDD pin; and a startup controlling unit controlling the startup switch.

The integrated circuit may further include a detecting switch interrupting a connection between the HV pin and the voltage dividing unit.

The startup switch may include a junction gate field-effect transistor (JFET); and the detecting switch may include the JFET.

According to another aspect of the present disclosure, an integrated circuit controlling a power supply may include: a drain pin obtaining startup power; a voltage dividing unit connected to the drain pin; and an input voltage detecting unit detecting an input voltage through voltage distribution by the voltage dividing unit.

The voltage dividing unit may include a plurality of resistors connected to each other in series.

The integrated circuit may further include a VDD pin transferring the startup power obtained by the drain pin to a capacitor.

The integrated circuit may further include: a startup switch interrupting a connection between the drain pin and the VDD pin; and a startup controlling unit controlling the startup switch.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a diagram illustrating a general flyback converter and an integrated circuit for controlling the flyback converter;

FIG. 2 is a diagram illustrating an integrated circuit according to an exemplary embodiment of the present disclosure and a power supply including the integrated circuit;

FIG. 3 is a diagram illustrating an integrated circuit according to another exemplary embodiment of the present disclosure and a power supply including the integrated circuit;

FIG. 4 is a diagram illustrating an example of a method of detecting input voltage information using an input voltage detecting unit of FIG. 3;

FIG. 5 is a diagram illustrating an integrated circuit according to another exemplary embodiment of the present disclosure and a power supply including the integrated circuit; and

FIG. 6 is a diagram illustrating an integrated circuit according to another exemplary embodiment of the present disclosure and a power supply including the integrated circuit.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

Throughout the drawings, the same or like reference numerals will be used to designate the same or like elements.

A configuration of a power supply will hereinafter be described based on a flyback converter for convenience of explanation in the present specification.

However, it will be appreciated by those skilled in the art that a configuration according to an exemplary embodiment of the present disclosure may be applied to a forward converter, a half-bridge converter, a full-bridge converter, a push-full converter, a resonance type converter, or the like.

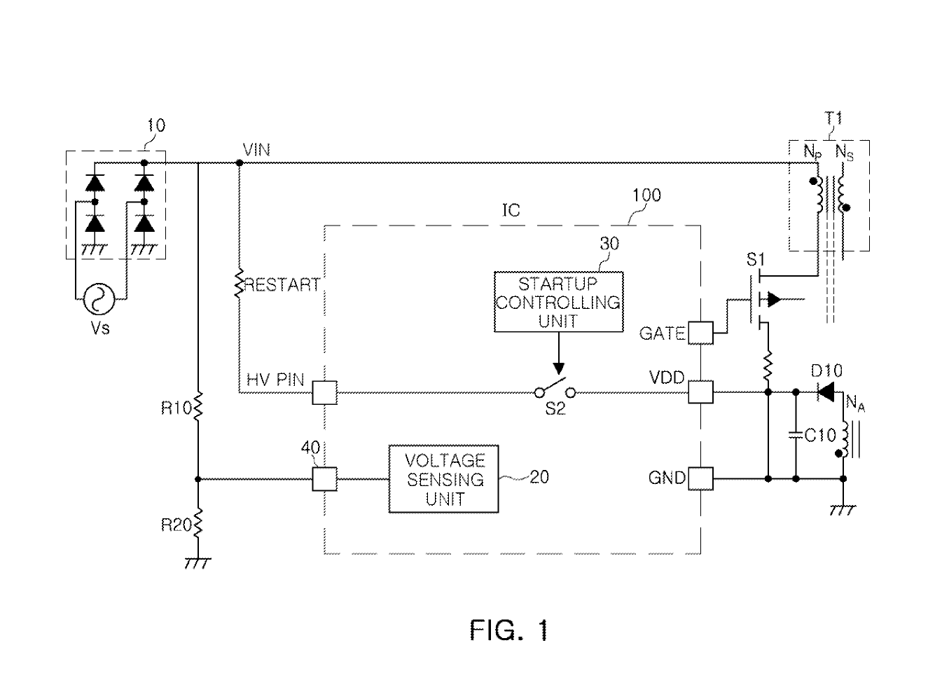

FIG. 1 is a diagram illustrating a general flyback converter and an integrated circuit for controlling the flyback converter.

Referring to FIG. 1, a flyback converter may include a power input unit Vs, a transformer T1, a rectifying unit 10, a switching element S1, and an integrated circuit 100.

The power input unit Vs may supply input power. The input power may be alternating current (AC) power.

The rectifying unit 10 may receive the AC power and rectify the received AC power to transfer the rectified AC power to the transformer T1.

The transformer T1 may have a primary winding Np and a secondary winding Ns, inductively coupled to the primary winding. Here, a region in which the primary winding Np is located may be defined as a primary side region and a region in which the secondary winding Ns is located may be defined as a secondary side region.

The switching element S1 may interrupt a primary current I1 flowing in the primary winding Np of the transformer.

The switching element S1 according to the exemplary embodiment of the present disclosure may be formed of one of an insulated gate bipolar transistor (IGBT), a metal oxide semiconductor field-effect transistor (MOS-FET) and a bipolar junction transistor (BJT).

Meanwhile, a rectifying diode D10 and a capacitor C10 for stabilizing power induced from the secondary winding Np may be located on the secondary side.

The rectifying diode may rectify a secondary current of the transformer T1.

The capacitor may stabilize power transferred from the rectifying diode.

Meanwhile, the flyback converter may further include an auxiliary winding NA. The auxiliary winding NA may be inductively coupled to the transformer T1. Therefore, in the case in which the power is induced to the primary winding Np and the secondary winding Ns, the power may also be induced to the auxiliary winding NA.

The power induced to the auxiliary winding NA may be provided to the integrated circuit 100 via the rectifying diode D10 and the stabilizing capacitor C10. For example, one terminal of the rectifying diode D10 may be coupled to a VDD pin of the integrated circuit, and the VDD pin may obtain the power induced from the auxiliary winding NA.

Meanwhile, the integrated circuit 100 may include an HV pin. The HV pin may charge the capacitor C10 connected to the VDD pin at the time of a startup. That is, since a case in which the integrated circuit is initially operated corresponds to an under voltage lock out (UVLO) situation, the capacitor C10 connected to the VDD pin may be charged and perform a startup operation.

Meanwhile, the integrated circuit 100 may include a startup switch S2 interrupting a connection between the HV pin and the VDD pin. In addition, the integrated circuit 100 may include a startup controlling unit 30 controlling the startup switch. For example, the startup controlling unit 30 may turn the startup switch S2 on at the time of the startup and turn the startup switch S2 off after the startup.

Meanwhile, in order for the integrated circuit 100 to control the flyback converter, the integrated circuit 100 may need to obtain input voltage information. Therefore, the integrated circuit may include a separate pin 40 for obtaining the input voltage information.

Referring to FIG. 1, the input power Vs may be divided by a plurality of resistors R10 and R20 which are connected to each other in series, and the input voltage information may be input to the pin 40.

The integrated circuit 100 may include a voltage sensing unit 20 for detecting the input voltage information and may detect the input voltage by the pin 40.

However, in this case, since the separate pin 40 for sensing the input voltage is required, manufacturing costs of the integrated circuit may be significantly increased.

In addition to the method described above, there is provided a method of sensing the input voltage information by a separate auxiliary winding without using the separate pin. However, in the case of the method of sensing the input voltage information using the auxiliary winding as described above, since a turn-on time in a burst mode is short, it may be difficult to accurately sense the input voltage information.

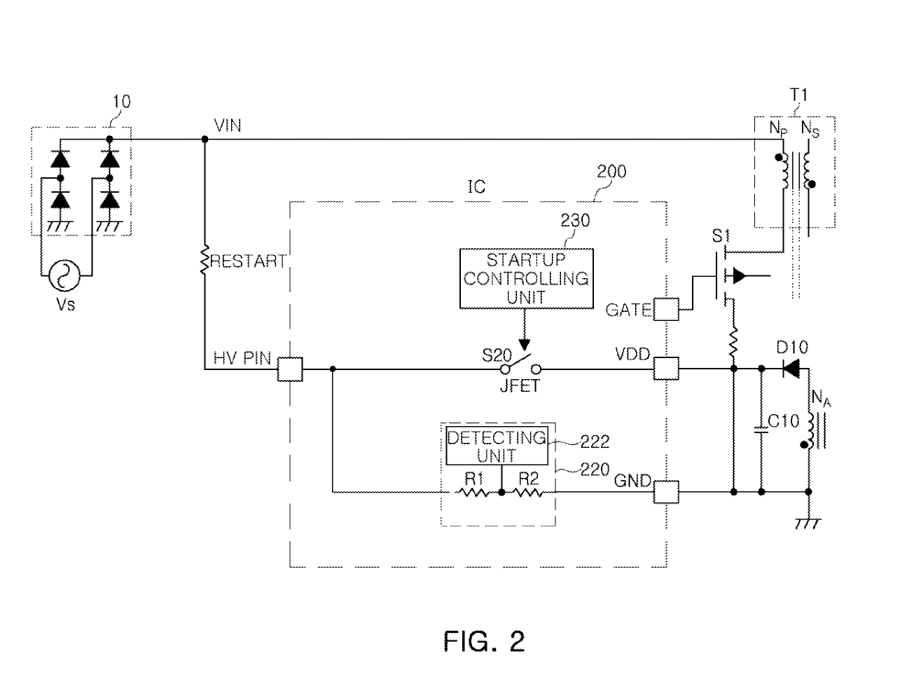

FIG. 2 is a diagram illustrating an integrated circuit 200 according to an exemplary embodiment of the present disclosure and a power supply including the integrated circuit 200.

Referring to FIG. 2, the power supply may include a power input unit Vs, a transformer T1, a rectifying unit 10, and a switching element S1, and the integrated circuit 200 may control the power supply.

The power input unit Vs may supply input power. The input power may be alternating current (AC) power.

The rectifying unit 10 may receive the AC power and rectify the received AC power to transfer the rectified AC power to the transformer T1.

The transformer T1 may have a primary winding Np and a secondary winding Ns, inductively coupled to the primary winding. Here, a region in which the primary winding Np is located may be defined as a primary side region and a region in which the secondary winding Ns is located may be defined as a secondary side region.

The switching element S1 may interrupt a primary current I1 flowing in the primary winding Np of the transformer.

The switching element S1 according to this exemplary embodiment of the present disclosure may be formed of one of an insulated gate bipolar transistor (IGBT), a metal oxide semiconductor field-effect transistor (MOS-FET) and a bipolar junction transistor (BJT).

Meanwhile, a rectifying diode D10 and a capacitor D10 for stabilizing power introduced from the secondary winding Np may be located on the secondary side.

The rectifying diode may rectify a secondary current of the transformer T1.

The capacitor element may stabilize power transferred from the rectifying diode.

Meanwhile, the flyback converter may further include an auxiliary winding NA. The auxiliary winding NA may be inductively coupled to the transformer T1. Therefore, in the case in which the power is induced to the primary winding Np and the secondary winding Ns, the power may also be induced to the auxiliary winding NA.

The power induced to the auxiliary winding NA may be provided to the integrated circuit 200 via the rectifying diode D10 and the stabilizing capacitor C10. For example, one terminal of the rectifying diode D10 may be coupled to a VDD pin of the integrated circuit, wherein the VDD pin may obtain the power induced from the auxiliary winding NA.

Meanwhile, the integrated circuit 200 may include an HV pin. The HV pin may charge the capacitor C10 connected to the VDD pin at the time of a startup. That is, since a case in which the IC is initially operated corresponds to an under voltage lock out (UVLO) situation, the capacitor C10 connected to the VDD pin may be charged and perform a startup operation.

Meanwhile, the integrated circuit 200 may include a startup switch S20 interrupting a connection between the HV pin and the VDD pin. In addition, the integrated circuit 200 may include a startup controlling unit 230 controlling the startup switch. For example, the startup controlling unit 230 may turn the startup switch S20 on at the time of the startup and turn the startup switch S20 off after the startup.

The startup switch S20 may include a junction gate field-effect transistor (JFET).

That is, the HV pin may obtain startup power. The power may be transferred to the VDD pin via the startup switch S20. The VDD pin may transfer the startup power obtained from the HV pin to the capacitor C10.

The integrated circuit 200 according to the exemplary embodiment of the present disclosure may obtain the input voltage information through the HV pin.

Referring to FIG. 2, the integrated circuit 200 may include a voltage dividing unit 220 connected to the HV pin. The voltage dividing unit 220 may include a plurality of resistors R1 and R2 connected to each other in series.

Meanwhile, the integrated circuit 200 may further include an input voltage detecting unit 222. The input voltage detecting unit 222 may detect the input voltage information through voltage distribution by the voltage dividing unit.

Referring to FIG. 2, a voltage detection value obtained by the input voltage detecting unit 222 may be expressed by the following Equation.

Voltage Detection Value=Vin*R2/(Rstart+R1+R2)

That is, the integrated circuit according to the exemplary embodiment of the present disclosure may obtain information of an input voltage Vin through the voltage detection value.

According to the exemplary embodiment of the present disclosure, the input voltage may be sensed by using the HV pin. Accordingly, a separate voltage sensing pin may be omitted, resulting in a reduction in manufacturing costs.

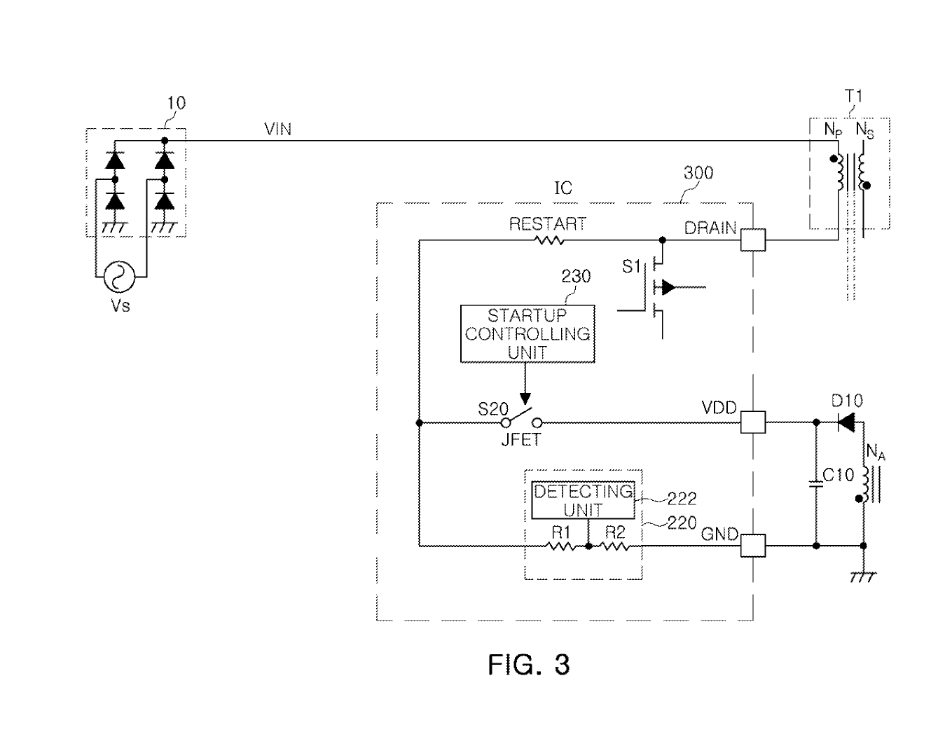

FIG. 3 is a diagram illustrating an integrated circuit 300 according to another exemplary embodiment of the present disclosure and a power supply including the integrated circuit 300.

Since the power input unit Vs, the rectifying unit 10, the transformer T1, the auxiliary winding NA, the rectifying diode D10, and the stabilizing capacitor C10 have been described above, detailed descriptions thereof will be omitted.

Meanwhile, the integrated circuit 300 may include a switching element S1 therein. The switching element S1 may interrupt a primary current I1 flowing in the primary winding Np of the transformer, as described above.

The switching element S1 according to this exemplary embodiment of the present disclosure may be formed of one of an insulated gate bipolar transistor (IGBT), a metal oxide semiconductor field-effect transistor (MOS-FET) and a bipolar junction transistor (BJT).

The integrated circuit 300 according to the exemplary embodiment of the present disclosure may include a drain pin. The drain pin may be connected to one terminal of the primary winding Np of the transformer T1.

The integrated circuit 300 according the exemplary embodiment of the present disclosure may obtain input voltage information through the drain pin.

Referring to FIG. 3, the integrated circuit 300 may include a voltage dividing unit 220 connected to the drain pin. The voltage dividing unit 220 may include a plurality of resistors R1 and R2 connected to each other in series.

Meanwhile, the integrated circuit 300 may further include an input voltage detecting unit 222. The input voltage detecting unit 222 may detect the input voltage information through voltage distribution by the voltage dividing unit.

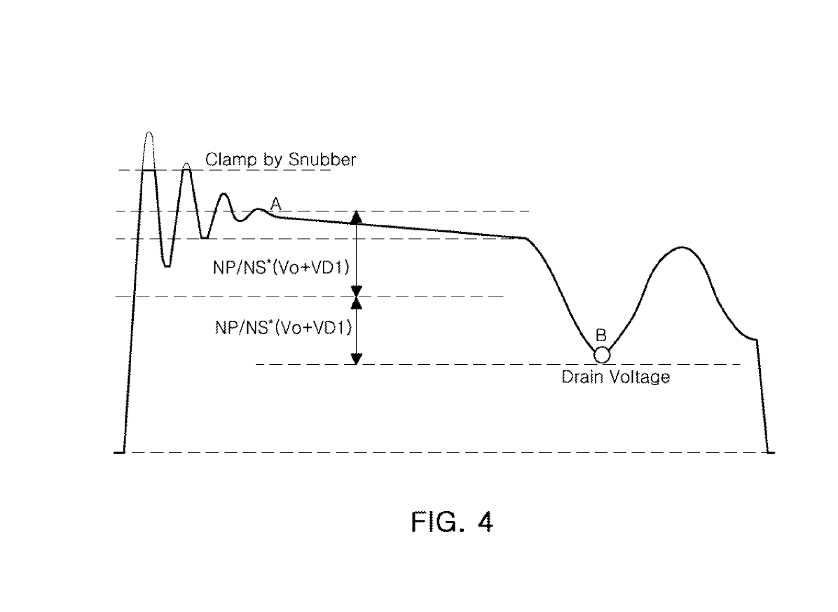

FIG. 4 is a diagram illustrating an example of a method of detecting input voltage information using the input voltage detecting unit 222 shown in FIG. 3.

FIG. 4 illustrates a drain voltage, wherein NP/NS refers to a winding ratio of the primary winding Np and the secondary winding Ns of the transformer T1 and V0+VD1 refers to an output voltage output from the secondary winding Ns.

Referring to FIG. 2, an intermediate point between a point A and a point B refers to the input voltage. That is, the point A may have a difference from the input voltage by Np/Ns*(Vo+VD1) and the point B may also have a difference from the input voltage by Np/Ns*(Vo+VD1).

Therefore, the measured value of the point A and the measured value of the point B may be added and may be then divided by 2 to thereby produce the input voltage Vin.

Meanwhile, a relationship between the detection value obtained by the input voltage detecting unit 222 and the input voltage may be expressed by the following Equation:

Voltage Detection Value=(A+B)/2*R2/(Rstart+R1+R2)

That is, the integrated circuit according to the exemplary embodiment of the present disclosure may obtain information of the input voltage Vin through the voltage detection value.

According to the exemplary embodiment of the present disclosure, the input voltage may be sensed by using the drain pin. Accordingly, a separate voltage sensing pin may be omitted, resulting in a reduction in manufacturing costs.

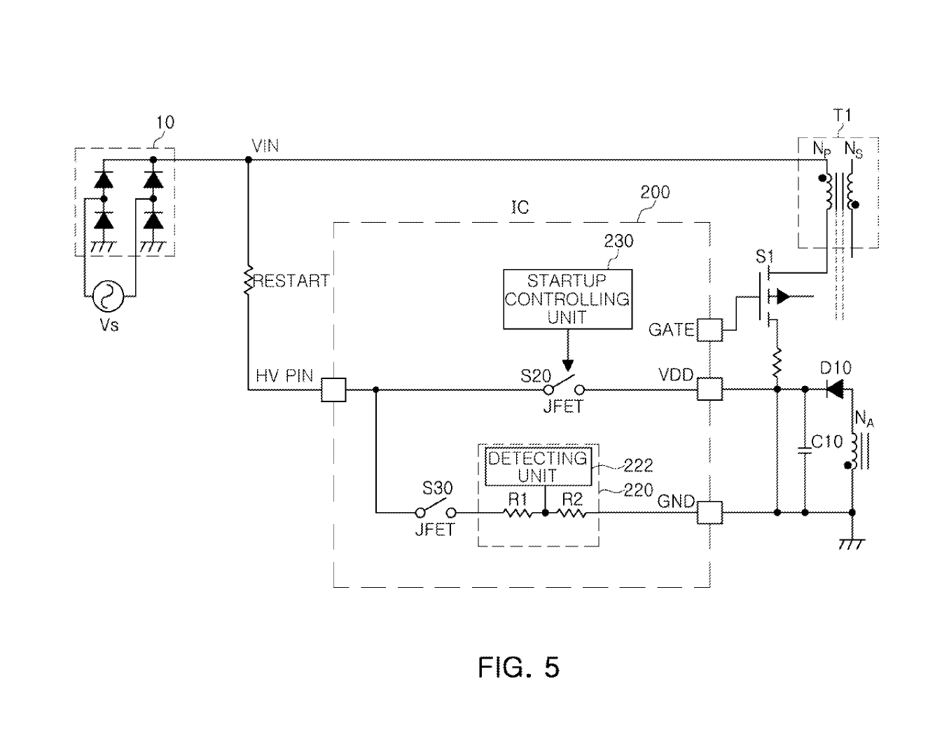

FIG. 5 is a diagram illustrating an integrated circuit 200 according to another exemplary embodiment of the present disclosure and a power supply including the integrated circuit 200.

Since the components of the integrated circuit except for a detecting switch S30 have been described in detail in the above-described embodiment of FIG. 2, the detecting switch S30 will be described below in detail.

The detecting switch S30 may interrupt a connection between the HV pin and the voltage dividing unit 220.

The detecting switch S30 may include a junction gate field-effect transistor (JFET).

The detecting switch S30 may be turned off at the time of the startup and may be turned on when the startup is terminated. An input voltage detecting unit 222 may not perform the voltage detection at the time of the startup and detect the input voltage when the startup is terminated.

According to this exemplary embodiment of the present disclosure, a leakage current at the time of the startup may be decreased.

Such a method may also be applied to the integrated circuit of FIG. 3, which detects the input voltage through the drain pin.

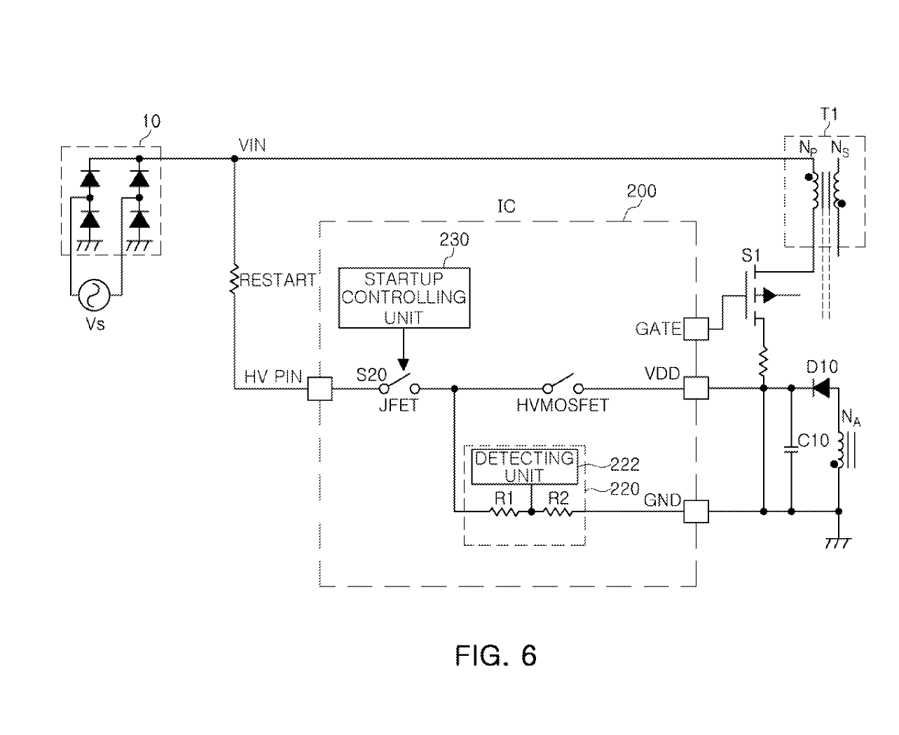

FIG. 6 is a diagram illustrating an integrated circuit 200 according to another exemplary embodiment of the present disclosure and a power supply including the integrated circuit 200.

According to the present exemplary embodiment, a voltage dividing unit 220 may be connected between a startup switch S20 and a ground terminal GND.

In the case in which the startup switch S20 is formed of a JFET, since voltage is detected at a rear stage of the startup switch S20, values of resistors R1 and R2 may be decreased.

Such a method may also be applied to the integrated circuit of FIG. 3, which detects the input voltage through the drain pin.

As set forth above, according to exemplary embodiments of the present disclosure, an integrated circuit capable of sensing input voltage using an HV pin and a drain pin may be provided.

In addition, according to exemplary embodiments of the present disclosure, an integrated circuit capable of reducing manufacturing costs by omitting a separate voltage sensing pin may be provided.

While exemplary embodiments have been shown and described above, it will be apparent to those skilled in the art that modifications and variations could be made without departing from the spirit and scope of the present disclosure as defined by the appended claims.

What is claimed is:

1. An integrated circuit controlling a power supply, the integrated circuit comprising:
an HV pin obtaining startup power;
a voltage dividing unit connected to the HV pin; and
an input voltage detecting unit detecting an input voltage through voltage distribution by the voltage dividing unit.

2. The integrated circuit of claim 1, wherein the voltage dividing unit includes a plurality of resistors connected to each other in series.

3. The integrated circuit of claim 1, further comprising a VDD pin transferring the startup power obtained by the HV pin to a capacitor.

4. The integrated circuit of claim 3, further comprising:
a startup switch interrupting a connection between the HV pin and the VDD pin; and
a startup controlling unit controlling the startup switch.

5. The integrated circuit of claim 4, further comprising a detecting switch interrupting a connection between the HV pin and the voltage dividing unit.

6. The integrated circuit of claim 5, wherein the startup switch includes a junction gate field-effect transistor (JFET); and
the detecting switch includes the JFET.

7. An integrated circuit controlling a power supply, the integrated circuit comprising:
a drain pin obtaining startup power;
a voltage dividing unit connected to the drain pin; and
an input voltage detecting unit detecting an input voltage through voltage distribution by the voltage dividing unit.

8. The integrated circuit of claim 7, wherein the voltage dividing unit includes a plurality of resistors connected to each other in series.

9. The integrated circuit of claim 7, further comprising a VDD pin transferring the startup power obtained by the drain pin to a capacitor.

10. The integrated circuit of claim 9, further comprising:
a startup switch interrupting a connection between the drain pin and the VDD pin; and
a startup controlling unit controlling the startup switch.
